(19) United States
(12) Patent Application Publication
(10) Pub. No.: US 2012/0273349 A1
(43) Pub. Date: Nov. 1, 2012

(54) Glass Substrate Trolley Handling System

(75) Inventor: Chao-Mu Chen, Shenzhen City (CN)

(73) Assignee: Shenzhen China Star Optoelectronics Technology Co. Ltd., Shenzhen City, Guangdong (CN)

(21) Appl. No.: 13/318,356

(22) PCT Filed: Jun. 23, 2011
(86) PCT No.: PCT/CN2011/076201

§ 371 Date: Oct. 31, 2011

(30) Foreign Application Priority Data
Apr. 29, 2011 (CN) 201120134712.4

(51) Int. Cl. C23C 14/34

(52) U.S. Cl. 204/298.25

(57) ABSTRACT

A glass substrate trolley handling system is disclosed. The glass substrate trolley handling system comprises an equipment outlet module, a cassette module, a bridging module, and an abnormal trolley returning module. The abnormal trolley returning module comprises a first operating mechanism for receiving an abnormal trolley from the equipment outlet module and a second operating mechanism for transferring the abnormal trolley to the bridging module. The bridging module comprises a third operating mechanism for receiving the abnormal trolley from the abnormal trolley returning module and a fourth operating mechanism for transferring the abnormal trolley to the cassette module. In this way, the cost of handling the empty trolley and the production capacity loss can be reduced to zero.

### FIELD OF THE INVENTION

The present disclosure generally relates to the technical field of liquid crystal display (LCD) manufacturing, and more particularly, to a glass substrate trolley handling system.

### BACKGROUND OF THE INVENTION

In the prior art, glass substrates of liquid crystal displays (LCDs) must be handled by a special transporting and handling system. For example, in a system for plating a film on a back side of a substrate, the glass substrate must be transported by a special transporting and handling system.

As shown in FIG. 1, the transporting and handling system comprises an equipment inlet module 96, an inlet rotating module 99, a vacuum sputtering unit 97, an outlet temporary storage module 90, an outlet returning module 98, a handling module 94, an equipment outlet module 93 and an inlet returning module 95 sequentially connected with each other to form a loop. Additionally, the transporting and handling system further comprises a cassette module 91 and a bridging module 92. As shown in FIG. 2, there is shown a schematic view of a process flow performed by the transporting and handling system in handling an abnormal trolley. Before returning from the equipment outlet module 93 to the cassette module 91, the abnormal trolley has to pass through the equipment inlet module 96, the vacuum sputtering unit 97, the outlet returning module 98 and the bridging module 92. As can be seen, in order to return to the cassette module 91, the abnormal trolley must travel through the modules of the transporting and handling system by a complete cycle.

The equipment inlet module 96 is used to combine and assemble a substrate to be processed with a trolley. The inlet rotating module 99 is used to rotate the trolley to a correct direction and feed it into the equipment for processing. The vacuum sputtering unit 97 is used to plate an indium tin oxide (ITO) film. The outlet temporary storage module 90 is used to temporarily store a trolley for which the processing has been completed. The outlet returning module 98 is used to return the trolley to the handling module 94. The handling module 94 is used to handle the trolley to the equipment outlet module 93. The equipment outlet module 93 is used to separate the substrate that has been processed from the trolley and transfer the substrate out of the equipment. The inlet returning module 95 is used to return the trolley to the equipment inlet module 96. The cassette module 91 is used to accommodate empty trolleys or serve as a storing space for abnormal trolleys. The bridging module 92 is connected with the cassette module 91 and is used to transfer a normal trolley or an abnormal trolley.

In the transporting and handling system described above, the abnormal trolley which cannot carry a substrate any longer must be passed in an empty state through the vacuum sputtering unit 97 to the cassette module 91 for recovery. This practice has the following four drawbacks:

1) transferring an empty trolley through the ITO film plating production line will waste the production cost of the ITO film plating production line (cost up issue);

2) transferring of the empty trolley leads to a reduced production capacity (capacity loss issue);

3) passing the empty trolley through the vacuum sputtering unit may cause a film to be plated on a back side of the substrate (product damage issue); and

4) this increases the burden of the heater cover and, consequently, shortens the service life of the heater cover (cost up issue).

For related glass substrate transporting technologies, reference may be made to China Patent Application No. 200510007600.1 which discloses a waste glass handling system for liquid crystal displays.

### SUMMARY OF THE INVENTION

An objective of one embodiment of the present disclosure is to provide a glass substrate trolley handling system, which can significantly lower the cost of transferring an empty trolley, reduce the production capacity loss and the possibility of plating a film on a back side of the substrate, reduce the amount of indium tin oxide (ITO) coated on the heater, and prolong the service life of parts of the system.

To achieve the aforesaid objective, one embodiment of the present invention provides a glass substrate trolley handling system, which comprises an equipment outlet module, a cassette module, a bridging module, an abnormal trolley returning module, a rotating module and an equipment inlet module. The abnormal trolley returning module comprises a first operating mechanism for receiving an abnormal trolley from the equipment outlet module and a second operating mechanism for transferring the abnormal trolley to the bridging module. The bridging module comprises a third operating mechanism for receiving the abnormal trolley from the abnormal trolley returning module and a fourth operating mechanism for transferring the abnormal trolley to the cassette module. The rotating module is adapted to adjust the abnormal trolley to a correct direction before the bridging module transfers the abnormal trolley to the cassette module. The equipment inlet module is adapted to receive a normal trolley from the equipment outlet module.

Preferably, the abnormal trolley returning module comprises an abnormal trolley exchanging unit, which is adapted to transfer a normal trolley stored at a predetermined location to the equipment inlet module when the abnormal trolley is received from the equipment outlet module so as to perform the handling task in place of the abnormal trolley.

Preferably, the bridging module comprises a bridging track unit, and the cassette module and the abnormal trolley exchanging unit transfer the abnormal trolley or the normal trolley by means of the bridging track unit.

Preferably, the system further comprises an inlet returning module, a vacuum sputtering module and an outlet returning module. The inlet returning module is disposed between the equipment outlet module and the equipment inlet module; the vacuum sputtering module is disposed between the equipment inlet module and the bridging module; and the outlet returning module is disposed between the vacuum sputtering module and the bridging module.

Preferably, the system further comprises an inlet rotating module disposed between the equipment inlet module and the vacuum sputtering module.

Preferably, the system further comprises a temporary storage module disposed between the vacuum sputtering module and the outlet returning module.

Preferably, the system further comprises a handling module disposed between the outlet returning module and the bridging module.

Preferably, the abnormal trolley exchanging unit further comprises a fifth operating mechanism disposed between the inlet returning module and the bridging module to temporarily store the normal trolley or the abnormal trolley.

To achieve the aforesaid objective, one embodiment of the present invention provides a glass substrate trolley handling system, comprising an equipment outlet module, a cassette module, a bridging module, and an abnormal trolley returning module. The abnormal trolley returning module comprises a first operating mechanism for receiving an abnormal trolley from the equipment outlet module and a second operating mechanism for transferring the abnormal trolley to the bridging module. The bridging module comprises a third operating mechanism for receiving the abnormal trolley from the abnormal trolley returning module and a fourth operating mechanism for transferring the abnormal trolley to the cassette module.

Preferably, the bridging module comprises a rotating module, which is adapted to adjust the abnormal trolley to a correct direction before the bridging module transfers the abnormal trolley to the cassette module.

Preferably, the system further comprises an equipment inlet module adapted to receive a normal trolley from the equipment outlet module.

Preferably, the abnormal trolley returning module comprises an abnormal trolley exchanging unit, which is adapted to transfer a normal trolley stored at a predetermined location to the equipment inlet module when the abnormal trolley is received from the equipment outlet module so as to perform the handling task in place of the abnormal trolley.

Preferably, the bridging module comprises a bridging track unit, and the cassette module and the abnormal trolley exchanging unit transfer the abnormal trolley or the normal trolley by means of the bridging track unit.

Preferably, the system further comprises an inlet returning module, a vacuum sputtering module and an outlet returning module. The inlet returning module is disposed between the equipment outlet module and the equipment inlet module; the vacuum sputtering module is disposed between the equipment inlet module and the bridging module; and the outlet returning module is disposed between the vacuum sputtering module and the bridging module.

Preferably, the system further comprises an inlet rotating module disposed between the equipment inlet module and the vacuum sputtering module.

Preferably, the system further comprises a temporary storage module disposed between the vacuum sputtering module and the outlet returning module.

Preferably, the system further comprises a handling module disposed between the outlet returning module and the bridging module.

Preferably, the abnormal trolley exchanging unit further comprises a fifth operating mechanism disposed between the inlet returning module and the bridging module to temporarily store the normal trolley or the abnormal trolley.

The present disclosure has the following benefits: as compared to the prior art where an abnormal trolley in an empty status must also be passed through the vacuum sputtering module and subjected to the vacuum sputtering process to cause a higher production cost, a lower production capacity, an undesirable film plated on the back side of the substrate and an increased burden of the heater, the present disclosure can return the abnormal trolley to the cassette module directly via the equipment outlet module, the bridging module and the abnormal trolley returning module before the abnormal trolley enters the production line again. This can lower the cost of transferring the empty trolley, reduce the production capacity loss and the possibility of film plating on the back side of the substrate, reduce the amount of ITO coated on the heater, and prolong the service life of the parts.

### BRIEF DESCRIPTION OF THE DRAWINGS

FIG. 1 is a schematic structural view of an embodiment of a glass substrate trolley handling system in the prior art.

FIG. 2 is a flowchart illustrating operations of the glass substrate trolley handling system in the prior art.

FIG. 3 is a schematic structural view of a first embodiment of a glass substrate trolley handling system according to the present disclosure.

FIG. 4 is a schematic structural view of a second embodiment of the glass substrate trolley handling system according to the present disclosure.

FIG. 5 is a schematic structural view of a third embodiment of the glass substrate trolley handling system according to the present disclosure.

FIG. 6 is a schematic view illustrating transferring of a trolley in the third embodiment of the glass substrate trolley handling system according to the present disclosure.

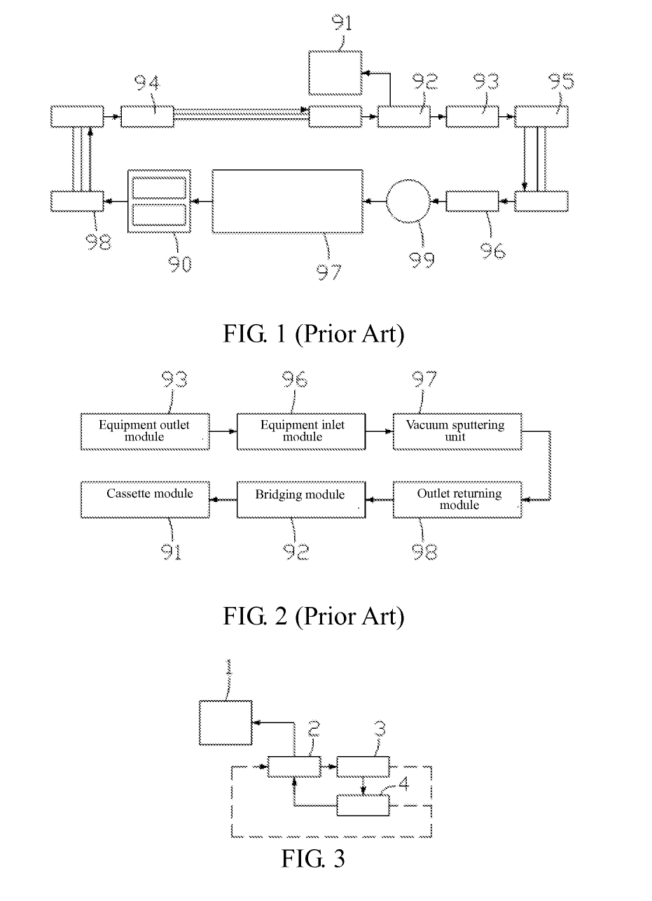

### DETAILED DESCRIPTION OF THE INVENTION

The present disclosure is more particularly described in the following examples that are intended as illustrative only since numerous modifications and variations therein will be apparent to those skilled in the art.

Referring to FIG. 3, there is shown a schematic structural view of a first embodiment of a glass substrate trolley handling system according to the present disclosure. The glass substrate trolley handling system of this embodiment comprises a cassette module 1, a bridging module 2, an equipment outlet module 3 and an abnormal trolley returning module 4.

The abnormal trolley returning module 4 comprises a first operating mechanism (not shown) for receiving an abnormal trolley from the equipment outlet module 3 and a second operating mechanism (not shown) for transferring the abnormal trolley to the bridging module 2.

The bridging module 2 comprises a third operating mechanism (not shown) for receiving the abnormal trolley from the abnormal trolley returning module 4 and a fourth operating mechanism (not shown) for transferring the abnormal trolley to the cassette module 1.

In this embodiment, by providing the cassette module 1, the bridging module 2, the equipment outlet module 3 and the abnormal trolley returning module 4, normal trolleys from the cassette module 1 are transferred to the equipment outlet module 3 via the bridging module 2, are then further transferred, plated with a film and handled, and finally return back to the equipment outlet module 3. When an abnormal trolley is found among a series of trolleys, the abnormal trolley can, after unloading the substrate carried thereon in the equipment outlet module 3, be returned to the cassette module 1 directly via the abnormal trolley returning module 4 and the bridging module 2 without being transferred, plated with a film and handled in an empty status. This can considerably lower the cost of handling the empty trolley, reduce the production capacity loss and the possibility of plating a film on the back side of the substrate, reduce the burden of the heater cover, and prolong the service life of the heater cover.

Through strict management, this can even lead to a zero cost of handling the empty trolley and a zero production capacity loss.

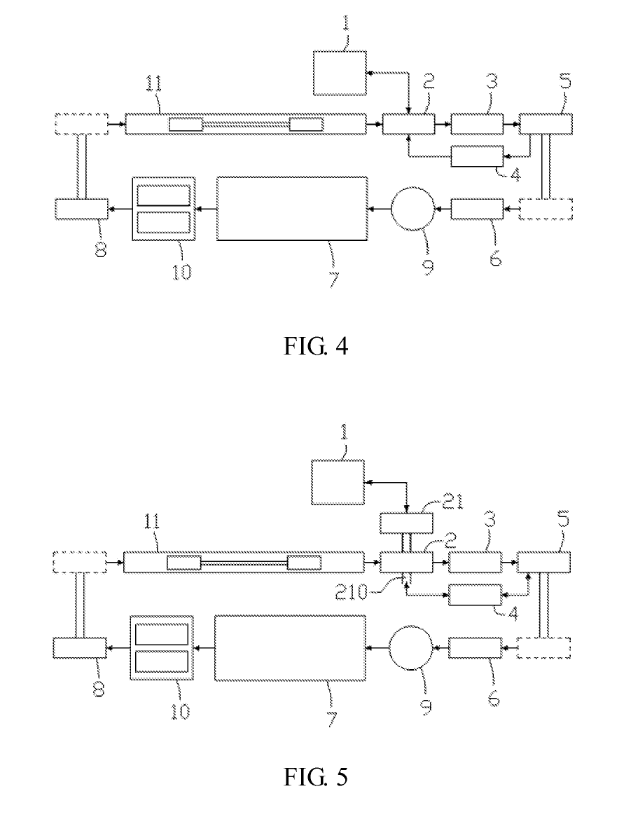

Referring to FIG. 4, there is shown a schematic structural view of a second embodiment of the glass substrate trolley handling system according to the present disclosure. The second embodiment differs from the first embodiment of the glass substrate trolley handling system only in that, the glass substrate trolley handling system of this embodiment further comprises an inlet returning module 5, an equipment inlet module 6, a vacuum sputtering module 7, an outlet returning module 8, an inlet rotating module 9, an outlet temporary storage module 10 and a handling module 11.

The inlet returning module 5 is disposed between the equipment outlet module 3 and the equipment inlet module 6 to return a normal trolley to the equipment inlet module 6. Meanwhile, the inlet returning module 5 is also able to receive an abnormal trolley and return the abnormal trolley to the abnormal trolley returning module 4 although its functions are not merely limited to this. Optionally, the inlet returning module 5 of this embodiment may also be integrated with the equipment outlet module 3.

The equipment inlet module 6 is disposed between the inlet return module 5 and the vacuum sputtering module 7 to receive a normal trolley, which has unloaded the substrate in the equipment outlet module 3 and then returned via the inlet returning module 5, and to load a glass substrate.

The vacuum sputtering module 7 is disposed between the equipment inlet module 6 and the bridging module 2 to receive a normal trolley returned from the equipment inlet module 6 and to plate a film on a glass substrate carried on the normal trolley.

The outlet returning module 8 is disposed between the vacuum sputtering module 7 and the bridging module 2 to receive a normal trolley carrying a glass substrate that has been plated with a film in the vacuum sputtering module 7.

Between the equipment inlet module 6 and the vacuum sputtering module 7 is further disposed an inlet rotating module 9, which is adapted to rotate a normal trolley transferred from the equipment inlet module 6 and carrying a glass substrate therein to a correct direction and then feed the normal trolley into the vacuum sputtering module 7.

Between the vacuum sputtering module 7 and the outlet returning module 8 is further disposed an outlet temporary storage module 10 to receive and temporarily store the normal trolley from the vacuum sputtering module 7.

The handling module 11 is disposed between the outlet returning module 8 and the bridging module 2 to handle a normal trolley from the outlet returning module 8 to the equipment outlet module 3.

Referring to FIG. 5, there is shown a schematic structural view of a third embodiment of the glass substrate trolley handling system according to the present disclosure. The bridging module 2 further comprises a rotating module 21. The rotating module 21 is used to adjust an abnormal trolley to a correct direction before the abnormal trolley is transferred by the bridging module 2 to the cassette module 1 so as to ensure a uniform direction of abnormal trolleys stored in the cassette module 1. In other embodiments, the rotating module 21 can be further used to adjust a normal trolley, which is transferred to the abnormal trolley returning module 4 for temporary storage, to a correct direction. By additionally providing the rotating module 21 in this embodiment, it can be ensured that all normal trolleys and abnormal trolleys are stored in the cassette module 1 in a uniform direction, and this can prevent fracture of a glass substrate when being put into a trolley in a wrong direction. Of course, the rotating module 21 and the bridging module 2 may be integrated together.

The bridging module 2 comprises a bridging track unit 210. The bridging module 2 is used to return an abnormal trolley to the cassette module 1 and transfer a normal trolley to the abnormal trolley returning module 4 via the bridging track unit 210. In this embodiment, by additionally providing the bridging track unit 210 in the bridging module 2, the abnormal trolley in the abnormal trolley returning module 4 can be automatically transferred to the cassette module 1.

In another embodiment of the present disclosure, the abnormal trolley returning module 4 also comprises an abnormal trolley exchanging unit (not shown). The abnormal trolley exchanging unit further comprises a fifth operating mechanism (not shown) disposed between the inlet returning module 5 and the bridging module 2 to temporarily store a normal trolley or an abnormal trolley. The abnormal trolley exchanging unit is used to replace an abnormal trolley received from the equipment outlet module 3 with a normal trolley stored at a predetermined location so that the handling task can be continued by the normal trolley. For example, a normal trolley from the fifth operating mechanism is transferred via the inlet returning module 5 to the equipment inlet module 6 to continue the handling task in place of the abnormal trolley. The fifth operating mechanism can also receive and temporarily store an abnormal trolley from the first operating mechanism of the abnormal trolley returning module 4. By using the abnormal trolley exchanging unit in this embodiment, the abnormal trolley can be replaced by the normal trolley to ensure smooth operation of the production line without interruption.

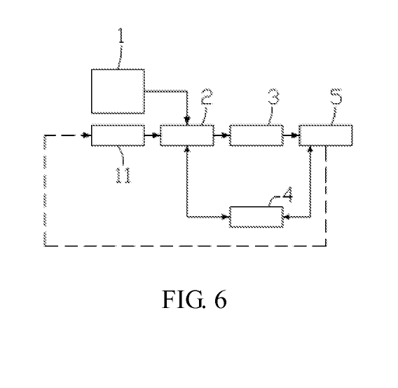

Referring to FIG. 6, there is shown a schematic view illustrating handling of a trolley in the third embodiment of the glass substrate trolley handling system according to the present disclosure. The handling process includes the following two stages.

Stage I: removing abnormal trolleys. if a trolley is determined by an engineer or detected by an apparatus or determined according to other criteria to be an abnormal one, then after the glass substrate carried by the trolley is unloaded in the equipment outlet module 3, the trolley will be transferred to the inlet returning module 5 and then returned from the inlet returning module 5 to the fifth operating mechanism of the abnormal trolley returning module 4 for temporary storage. Then, the abnormal trolley is passed through the abnormal trolley exchanging unit and returned back to the cassette module 1 via the bridging module 2. This process can shorten the path along which the abnormal trolley returns to the cassette module 1, considerably lower the cost of handling the empty trolley, reduce the production capacity loss and the possibility of plating a film on the back side of the substrate, reduce the burden of the heater cover, and prolong the service life of the heater cover.

Stage II: replenishing normal trolleys. Normal trolleys may be replenished in two ways. In a first way, at the same time when an abnormal trolley is being transferred to the fifth operating mechanism of the abnormal trolley exchanging unit, a normal trolley is transferred by the abnormal trolley exchanging unit to the inlet returning module 5 and then transferred from the inlet returning module 5 to the equipment inlet module 6. In this way, a normal trolley can be put into the glass substrate trolley handing system immediately when an abnormal trolley is found. Thus, the production process can run smoothly without interruption and the number of normal trolleys in the equipment can be maintained to reduce variations in the production process and guarantee quality of the products.

In a second way, when the fifth operating mechanism of the abnormal trolley exchanging unit becomes empty of normal trolleys, the glass substrate trolley handling system will replenish the fifth operating mechanism with one or more normal trolleys for storage therein when the bridging module 2 is in a waiting or idle status. This ensures that the time needed to exchange an abnormal trolley with a normal trolley is shortened. Meanwhile, in case an abnormal trolley arises, a normal trolley stored in the fifth operating mechanism can be replenished into the glass substrate trolley handling system immediately when the abnormal trolley is recalled. Thus, the production process can run smoothly without interruption and the number of normal trolleys in the equipment can be maintained to reduce variations in the production process and guarantee quality of the products.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A glass substrate trolley handling system, comprising an equipment outlet module, a cassette module, a bridging module, an abnormal trolley returning module, a rotating module and an equipment inlet module, wherein:
the abnormal trolley returning module comprises a first operating mechanism for receiving an abnormal trolley from the equipment outlet module and a second operating mechanism for transferring the abnormal trolley to the bridging module;
the bridging module comprises a third operating mechanism for receiving the abnormal trolley from the abnormal trolley returning module and a fourth operating mechanism for transferring the abnormal trolley to the cassette module;
the rotating module is adapted to adjust the abnormal trolley to a correct direction before the bridging module transfers the abnormal trolley to the cassette module; and
the equipment inlet module is adapted to receive a normal trolley from the equipment outlet module.

2. The system of claim 1, wherein the abnormal trolley returning module comprises:
an abnormal trolley exchanging unit for transferring a normal trolley stored at a predetermined location to the equipment inlet module when the abnormal trolley is received from the equipment outlet module so as to perform the handling task in place of the abnormal trolley.

3. The system of claim 2, wherein the bridging module comprises a bridging track unit, and the cassette module and the abnormal trolley exchanging unit transfer the abnormal trolley or the normal trolley by means of the bridging track unit.

4. The system of claim 2, further comprising an inlet returning module, a vacuum sputtering module and an outlet returning module, wherein:
the inlet returning module is disposed between the equipment outlet module and the equipment inlet module;
the vacuum sputtering module is disposed between the equipment inlet module and the bridging module; and
the outlet returning module is disposed between the vacuum sputtering module and the bridging module.

5. The system of claim 4, further comprising:
an inlet rotating module, being disposed between the equipment inlet module and the vacuum sputtering module.

6. The system of claim 5, further comprising:
a temporary storage module, being disposed between the vacuum sputtering module and the outlet returning module.

7. The system of claim 6, further comprising:
a handling module, being disposed between the outlet returning module and the bridging module.

8. The system of claim 4, wherein the abnormal trolley exchanging unit further comprises a fifth operating mechanism disposed between the inlet returning module and the bridging module to temporarily store the normal trolley or the abnormal trolley.

9. A glass substrate trolley handling system, comprising an equipment outlet module, a cassette module, a bridging module, and an abnormal trolley returning module, wherein:
the abnormal trolley returning module comprises a first operating mechanism for receiving an abnormal trolley from the equipment outlet module and a second operating mechanism for transferring the abnormal trolley to the bridging module; and
the bridging module comprises a third operating mechanism for receiving the abnormal trolley from the abnormal trolley returning module and a fourth operating mechanism for transferring the abnormal trolley to the cassette module.

10. The system of claim 9, wherein the bridging module comprises:
a rotating module, being adapted to adjust the abnormal trolley to a correct direction before the bridging module transfers the abnormal trolley to the cassette module.

11. The system of claim 9, further comprising:
an equipment inlet module, being adapted to receive a normal trolley from the equipment outlet module.

12. The system of claim 11, wherein the abnormal trolley returning module comprises:
an abnormal trolley exchanging unit for transferring a normal trolley stored at a predetermined location to the equipment inlet module when the abnormal trolley is received from the equipment outlet module so as to perform the handling task in place of the abnormal trolley.

13. The system of claim 12, wherein the bridging module comprises a bridging track unit, and the cassette module and the abnormal trolley exchanging unit transfer the abnormal trolley or the normal trolley by means of the bridging track unit.

14. The system of claim 12, further comprising an inlet returning module, a vacuum sputtering module and an outlet returning module, wherein:
the inlet returning module is disposed between the equipment outlet module and the equipment inlet module;
the vacuum sputtering module is disposed between the equipment inlet module and the bridging module; and
the outlet returning module is disposed between the vacuum sputtering module and the bridging module.

15. The system of claim 14, further comprising:
an inlet rotating module, being disposed between the equipment inlet module and the vacuum sputtering module.

16. The system of claim 15, further comprising:
a temporary storage module, being disposed between the vacuum sputtering module and the outlet returning module.

17. The system of claim 16, further comprising:
a handling module, being disposed between the outlet returning module and the bridging module.

18. The system of claim 14, wherein the abnormal trolley exchanging unit further comprises a fifth operating mechanism disposed between the inlet returning module and the bridging module to temporarily store the normal trolley or the abnormal trolley.
